(19) United States
(12) Patent Application Publication
(10) Pub. No.: US 2026/0260858 A1
(43) Pub. Date: Sep. 3, 2026

(54) ENDPOINT DETECTION USING SPECTRAL OR TEMPORAL PATTERN MATCHING

(71) Applicant: LAM RESEARCH CORPORATION, Fremont, CA (US)

(72) Inventors: Jindoo CHOI, Alameda, CA (US); Jeffrey D. BONDE, Redwood City, CA (US); Jorge LUQUE, Redwood City, CA (US)

(21) Appl. No.: 19/163,117

(22) PCT Filed: Mar. 4, 2024
(86) PCT No.: PCT/US2024/018315

§ 371 Date: Sep. 8, 2025

Related U.S. Application Data
(60) Provisional application No. 63/451,739, filed on Mar. 13, 2023.

(51) Int. Cl. H01J 37/32; G01N 21/31; G01N 21/55; G01N 21/71; H10P 74/00

(52) U.S. Cl. CPC H01J 37/32963; G01N 21/31; G01N 21/55; G01N 21/71; H01J 37/32972; H10P 74/238; H01J 2237/24585

(57) ABSTRACT

An endpoint detection system to detect an endpoint of treatment of a substrate in a processing chamber includes a first sensor configured to generate a first plurality of signals in response to one of an intensity of plasma light within a processing chamber, reflectometry from a surface of a substrate in the processing chamber, and absorption of process gases or byproducts evacuated from the processing chamber. A controller is configured to calculate a first plurality of correlation coefficients in response to the first plurality of signals, respectively, and a reference signal and detect an endpoint of the treatment in response to the first plurality of correlation coefficients.

### CROSS-REFERENCE TO RELATED APPLICATIONS

This application claims the benefit of U.S. Provisional Application No. 63/451,739, filed on Mar. 13, 2023. The entire disclosure of the application referenced above is incorporated herein by reference.

### FIELD

The present disclosure relates to substrate processing systems, and more particularly to endpoint detection in substrate processing systems using spectral or temporal pattern matching.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include deposition, etching, cleaning and other treatments. A substrate is arranged on a substrate support in a processing chamber of the substrate processing system. During processing, process gas mixtures may be introduced into the processing chamber. Plasma may be used to initiate chemical reactions.

During substrate treatment, endpoint detection (EPD) is important for substrate uniformity, maintaining accurate critical dimensions (CDs) and profile control, throughput improvement, and/or yield. However, process and wafer structural characteristics (e.g., low etch rates (ER), low open-area ratios and/or high aspect ratio (HAR) structures) may hinder accurate EPD. Under these circumstances, EPD is difficult due to a significant decrease in a signal-to noise ratio (SNR).

### SUMMARY

An endpoint detection system to detect an endpoint of treatment of a substrate in a processing chamber includes a first sensor configured to generate a first plurality of signals in response to one of an intensity of plasma light within a processing chamber, reflectometry from a surface of a substrate in the processing chamber, and absorption of process gases or byproducts evacuated from the processing chamber. A controller is configured to calculate a first plurality of correlation coefficients in response to the first plurality of signals, respectively, and a reference signal and detect an endpoint of the treatment in response to the first plurality of correlation coefficients.

In other features, the first plurality of signals comprise spectral signals. The first plurality of signals comprise temporal signals. The first plurality of signals comprise spectral signals and temporal signals. The first sensor comprises an optical emission spectroscopy sensor. The first sensor comprises a reflectometry sensor.

In other features, the controller is configured to detect the endpoint for the substrate in response to a maximum value of the first plurality of correlation coefficients for the substrate. The controller is configured to detect the endpoint for the substrate in response to a minimum value of the first plurality of correlation coefficients following a maximum value of the first plurality of correlation coefficients for the substrate. The controller is configured to detect the endpoint for the substrate in response to a minimum value of the first plurality of correlation coefficients for the substrate.

In other features the reference signal is based on one or more signals generated at one or more endpoints for one or more reference substrates. A second sensor is configured to generate a second plurality of signals in response to another one of optical intensity of process gases within the processing chamber, reflectometry from a surface of a substrate in the processing chamber, and absorption of process gases evacuated from the processing chamber.

In other features, the controller is configured to calculate a second plurality of correlation coefficients in response to the second plurality of signals, respectively, and a reference signal and detect the endpoint of the treatment in response to at least one of the first plurality of correlation coefficients and the second plurality of correlation coefficients. The controller is configured to detect the endpoint of the treatment in response to both the first plurality of correlation coefficients and the second plurality of correlation coefficients.

A method for detecting an endpoint of a treatment of a substrate in a processing chamber includes generating a first plurality of signals in response to one of optical intensity of process gases within the processing chamber, reflectometry from a surface of a substrate in the processing chamber, and absorption of process gases evacuated from the processing chamber; calculating a first plurality of correlation coefficients in response to the first plurality of signals, respectively, and a reference signal; and detecting an endpoint of the treatment in response to the first plurality of correlation coefficients.

In other features, the first plurality of signals comprise spectral signals. The first plurality of signals comprise temporal signals. The first plurality of signals are generated by an optical emission spectroscopy sensor. The first plurality of signals are generated by a reflectometry sensor.

In other features, the method includes detecting the endpoint for the substrate in response to a maximum value of the first plurality of correlation coefficients for the substrate. The method includes detecting the endpoint for the substrate in response to a minimum value of the first plurality of correlation coefficients following a maximum value of the first plurality of correlation coefficients for the substrate. The method includes detecting the endpoint for the substrate in response to a minimum value of the first plurality of correlation coefficients for the substrate. The reference signal is based on one or more signals generated at one or more endpoints for one or more reference substrates.

In other features, the method include generating a second plurality of signals in response to another one of optical intensity of process gases within the processing chamber, reflectometry from a surface of a substrate in the processing chamber, and absorption of process gases evacuated from the processing chamber. The method includes calculating a second plurality of correlation coefficients in response to both the second plurality of signals, respectively, and a reference signal; and detecting the endpoint of the treatment in response to at least one of the first plurality of correlation coefficients and the second plurality of correlation coefficients. The method includes detecting the endpoint of the treatment in response to the first plurality of correlation coefficients and the second plurality of correlation coefficients. The first plurality of signals are generated by an absorption sensor.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1 to 3 are functional block diagrams of examples of substrate processing systems including endpoint detection systems according to the present disclosure;

FIGS. 4 to 6 are examples of sensor signals generated by optical intensity, absorption, or reflectometry sensors, respectively, according to the present disclosure;

FIGS. 7 and 8 are functional block diagrams of examples of controllers for the endpoint detection systems according to the present disclosure;

FIG. 9 is a graph illustrating an example of correlation coefficients as a function of time; and

FIG. 10 is a flowchart illustrating an example of a method for performing endpoint detection according to the present disclosure.

In the drawings, reference numbers may be reused to identify similar and/or identical elements.

### DETAILED DESCRIPTION

EPD can be used in substrate processing systems that perform different types of substrate treatments such as etching, deposition, ashing, and/or other substrate treatments. EPD can also be performed using several types of sensors. Examples of sensors include optical intensity sensors, absorption sensors, reflectometry sensors, etc.

EPD using an optical emission spectroscopy (OES) sensor monitors optical intensity at one or more predetermined wavelengths during substrate treatment. The optical intensities at the one or more predetermined wavelengths or their temporal changes are compared to predetermined thresholds and EPD is performed based on the comparison. If the changes in optical intensity are small (as is the case for most difficult EPD cases), the SNR is low, which leads to inaccurate EPD. Signal intensity drift or wafer-to-wafer random fluctuations may further reduce the reliability of the EPD using this approach.

EPD using a reflectometry sensor monitors temporal patterns of reflected light at one or more predetermined wavelengths during substrate treatment. The temporal patterns at the one or more predetermined wavelengths are compared to predetermined thresholds and EPD is performed based on the comparison. For simple applications (e.g. large open area ratio, complete removal of film made of a material, presence of a clearly defined material interface, etc.), it is relatively easy to detect the endpoint. However, in cases where a process needs to be stopped midway to a target (e.g., recess depth or remaining film thickness), it is very difficult to perform EPD accurately.

EPD using an absorption sensor monitors the intensity of light absorbed by one or more byproducts of a substrate treatment. The absorption at one or more predetermined wavelengths is compared to predetermined thresholds and EPD is performed based on the comparison. The endpoint of the substrate treatment is determined based on changes in the absorption of the one or more byproducts. However, low open-area ratios and/or low etch rates may lead to low byproduct concentrations in the processing chamber and low absorption levels. Low absorption levels correspond to low SNR and inaccurate endpoint detection. Signal intensity drift or spectral drift may further reduce the reliability of the EPD using this approach.

An endpoint detection system according to the present disclosure employs pattern matching to enhance the SNR of a sensor and improve EPD accuracy and robustness. More particularly, the endpoint detection system calculates correlation coefficients between a sensor signal and a reference signal in time or frequency. In some examples, the reference signal corresponds a composite of one or more sensor signals from one or more substrates with the correct endpoint (e.g., a golden reference). For example, an average of multiple sensor signals with the correct endpoint can be used. The correlation coefficients quantify similarity between processing of the current substrate and the one or more substrates with correct endpoints.

The endpoint detection system according to the present disclosure allows more accurate detection of the endpoint. The endpoint detection system utilizes the spectral or temporal data from the sensor for a continuous range of wavelengths (rather than one or a few wavelengths) or a continuous time period and determines when the spectral or temporal data matches the one or more substrates corresponding to the reference signal. The correlation coefficient has a value in a range from −1 to 1, where ±1 correspond to the highest correlation and 0 corresponds to the lowest correlation.

The endpoint detection system according to the present disclosure provides multiple benefits as compared to conventional EPD methods. Background noise is largely eliminated during calculation of the correlation coefficients. As a result, the SNR is greatly increased, which leads to more accurate EPD. In addition, the effect of intensity shifts and/or fluctuations are minimized since the correlation coefficient is not adversely affected by changes in scale or offsets in signal intensity.

The endpoint detection system according to the present disclosure mitigates negative effects that are detrimental to reliable endpoint detection arising from spectral shifts, e.g. changes in wavelength calibration from the light source or detector errors. For example, this can be done by shifting or scaling the reference signal relative to the current sensor signal (or vice versa) prior to calculating the correlation coefficient.

In some examples, the endpoint detection system determines the endpoint based on outputs from more than one sensor. Correlation coefficients are generated based on sensor signals from each of the sensors and corresponding reference signals. In some examples, EPD is based multiple sets of correlation coefficients from the different sensors. The endpoint detection system can also be used in combination with conventional EPD methods. When used with conventional EPD methods, the endpoint detection system can act as a primary method that is confirmed by the conventional EPD approach or vice versa.

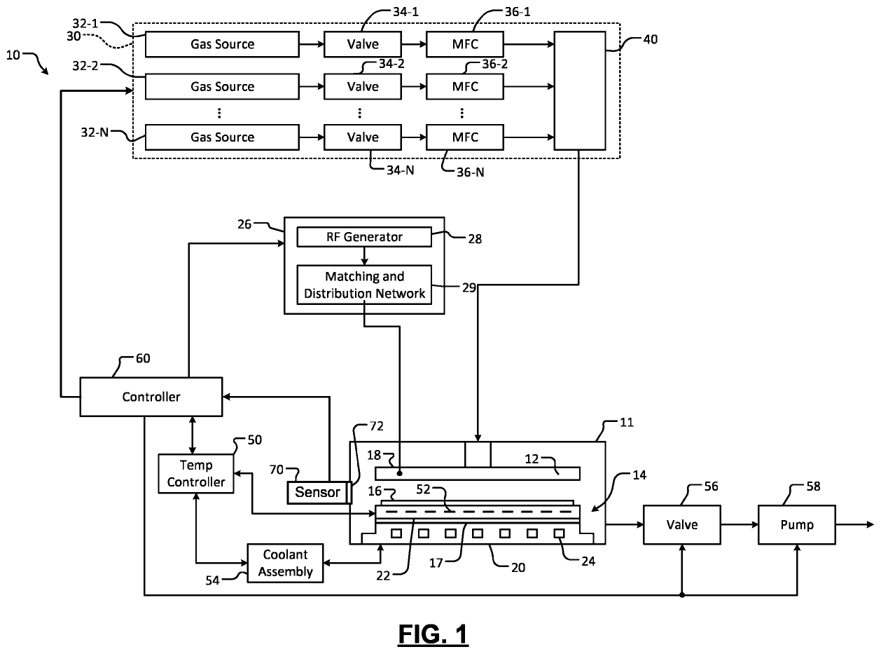

Referring now to FIGS. 1 to 3, examples of substrate processing systems including endpoint detection systems with different types of sensors arranged in in different locations are shown for performing EPD. In FIG. 1, a substrate processing system 10 includes a processing chamber 11 enclosing other components of the substrate processing system 10 and containing RF plasma (if used). The processing chamber 11 comprises an upper electrode 12 and an electrostatic chuck (ESC) 14 or other substrate support. During operation, a substrate 16 is arranged on the ESC 14.

For example, the upper electrode 12 may include a gas distribution device 18 such as a showerhead that introduces and distributes process gases. The gas distribution device 18 may include a stem portion including one end connected to a top surface of the processing chamber 11. A base portion of the showerhead is generally cylindrical and extends radially outwardly from an opposite end of the stem portion at a location that is spaced from the top surface of the processing chamber 11. A substrate-facing surface or faceplate of the base portion of the showerhead includes a plurality of holes through which vaporized precursor, process gas, or purge gas flows. Alternately, the upper electrode 12 may include a conducting plate, and the process gases may be introduced in another manner.

The ESC 14 comprises a baseplate 20 that acts as a lower electrode. The baseplate 20 supports a heating plate 22, which may correspond to a ceramic multi-zone heating plate. A bonding layer 17 may be arranged between the heating plate 22 and the baseplate 20. The baseplate 20 may include one or more channels 24 for flowing coolant through the baseplate 20.

If plasma is used, an RF generating system 26 generates and outputs an RF voltage to one of the upper electrode 12 and the lower electrode (e.g., the baseplate 20 of the ESC 14). The other one of the upper electrode 12 and the baseplate 20 may be DC grounded, AC grounded, or floating. For example, the RF generating system 26 may include an RF generator 28 that generates RF power that is fed by a matching and distribution network 29 to the upper electrode 12 or the baseplate 20.

A gas delivery system 30 includes one or more gas sources 32-1, 32-2, . . . , and 32-N (collectively gas sources 32), where N is an integer greater than zero. The gas sources 32 are connected by valves 34-1, 34-2, . . . , and 34-N (collectively valves 34) and mass flow controllers 36-1, 36-2, . . . , and 36-N (collectively mass flow controllers 36) to a manifold 40. An output of the manifold 40 is fed to the processing chamber 11. The gas sources supply process gas, precursors, etching gas, inert gas, carrier gas, etc.

A temperature controller 50 may be connected to a plurality of thermal control elements (TCEs) 52 arranged in the heating plate 22. The temperature controller 50 may be used to control the plurality of TCEs 52 to control a temperature of the ESC 14 and the substrate 16. The temperature controller 50 may communicate with a coolant assembly 54 to control coolant flowing through the channels 24. For example, the coolant assembly 54 may include a coolant pump, a reservoir, and one or more temperature sensors (not shown). The temperature controller 50 operates the coolant assembly 54 to selectively flow the coolant through the channels 24 to cool the ESC 14. A valve 56 and pump 58 may be used to control vacuum pressure in the processing chamber 11 and/or to evacuate reactants from the processing chamber 11.

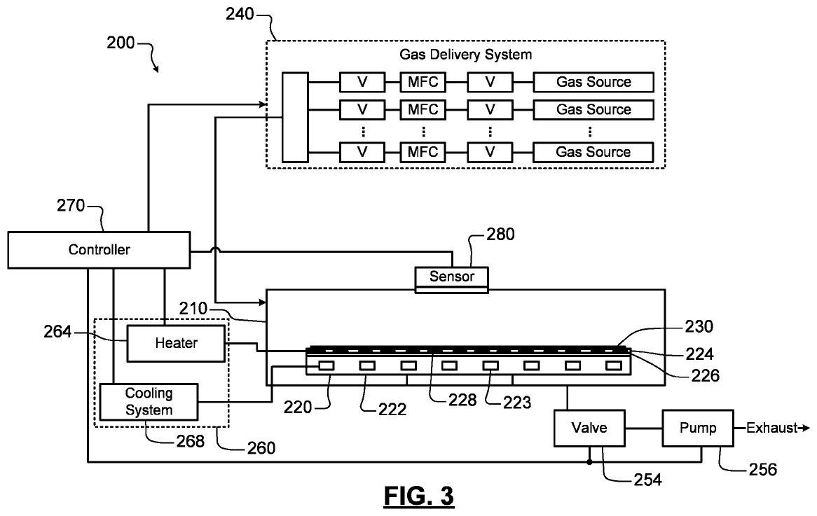

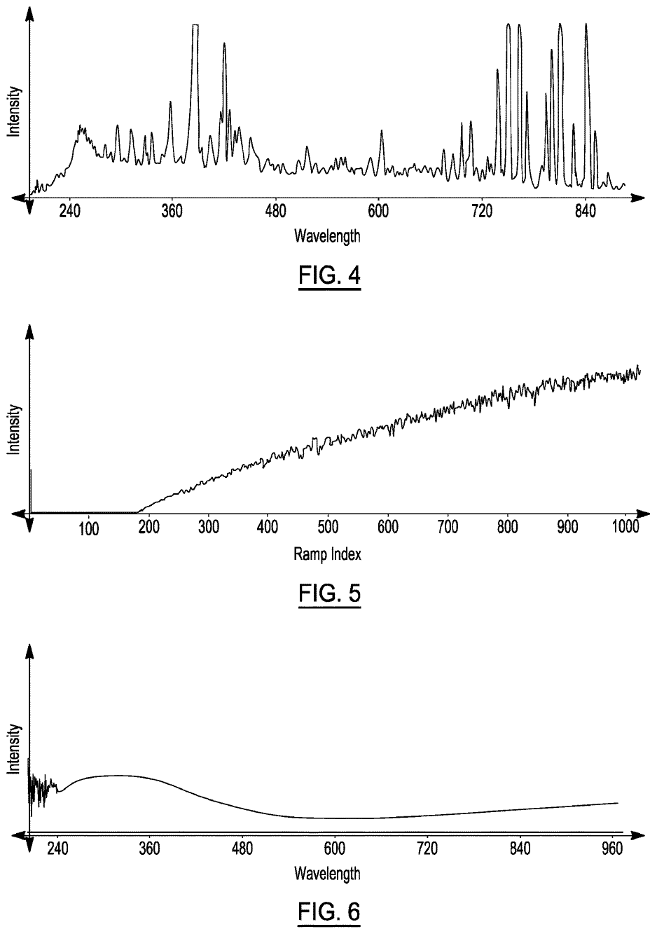

A system controller 60 controls timing of the process, supply of gas mixtures, pressure within the processing chamber 11, etc. An optical intensity sensor 70 such as an optical emission spectroscopy (OES) sensor is arranged adjacent to a window 72 in a wall of the processing chamber 11. The optical intensity sensor 70 is directed to a volume between the upper electrode 12 and the ESC 14. The optical intensity sensor 70 generates optical intensity signals at a predetermined sampling rate and in a predetermined frequency range. In some examples, the predetermined wavelength range is between 100 nm and 900 nm. An example of the optical intensity signal is shown in FIG. 4. As will be described further below, the optical intensity signals are correlated with a reference signal and EPD is performed based on the correlation values that are generated.

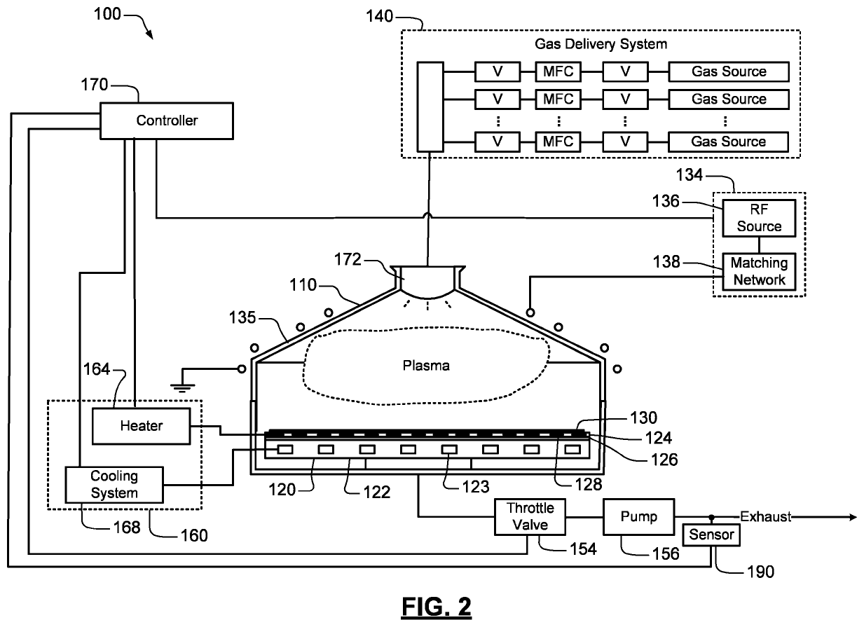

In FIG. 2, a substrate processing system 100 performs substrate treatments using inductively coupled plasma (ICP). The substrate processing system 100 includes a processing chamber 110. In some examples, the processing chamber 110 has a dome shape, although other shapes can be used. A substrate support 120 is arranged in the processing chamber 110. In some examples, the substrate support 120 includes a baseplate 122 including cooling passages 123 and a top plate 124 attached by a bonding layer 126 to the baseplate 122. A substrate 130 is supported on the substrate support 120 during processing.

A gas delivery system 140 supplies gas mixtures including process gas, inert gas, carrier gas, purge gas, etch gas or other gas mixtures to the processing chamber 110. A plasma generating system 134 selectively supplies RF power to inductive coils 135 arranged around the processing chamber 110. The inductive coils 135 induce magnetic fields in the processing chamber to strike and/or maintain plasma in the chamber. In some examples, the plasma generating system 134 includes an RF source 136 to supply an RF voltage and a matching network 138 to match an impedance of the inductive coils 135 to the RF source 136. A throttle valve 154 and a pump 156 evacuate reactants from the processing chamber 110 and/or control pressure within the processing chamber 110.

A temperature control system 160 is configured to control a temperature of the substrate 130 during processing. In some examples, a heater controller 164 supplies power to resistive heaters 128 arranged in the top plate 124. A cooling system 168 supplies a cooling fluid to the cooling passages 123 in the baseplate 122.

A controller 170 is configured to control the process. The controller 170 is configured to control the gas mixtures supplied by the gas delivery system 140, and RF power supplied by the plasma generating system 134. The controller 170 is further configured to control a temperature of the substrate 130 during processing using the temperature control system 160. The controller 170 is also configured to control pressure within the processing chamber 110 and/or to evacuate reactants from the processing chamber 110 using the throttle valve 154 and the pump 156.

An absorption sensor 190 senses absorption of exhaust gas in exhaust lines 192. The absorption sensor 190 generates absorption signals at a predetermined sampling rate and in a predetermined frequency range. In some embodiments, the wavelengths are in a range from 1 μm to 20 μm. In some embodiments, the wavelengths are in a range from 1 μm to 10 μm. An example of a spectral signal is shown in FIG. 5. As will be described further below, the spectral signals are correlated with a reference signal and EPD is performed based on the correlation values that are generated.

In FIG. 3, a substrate processing system 200 including a processing chamber 210 and a gas delivery system 240 is shown. A substrate support 220 is arranged in the processing chamber 210. In some examples, the substrate support 220 includes a baseplate 222 including cooling passages 223 and a top plate 224 attached by a bonding layer 226 to the baseplate 222. A substrate 230 is supported on the substrate support 220 during processing.

The gas delivery system 240 supplies gas mixtures including process gas, inert gas, carrier gas, purge gas, etch gas or other gas mixtures to the processing chamber 210. A valve 254 and a pump 256 evacuate reactants from the processing chamber 210 and/or control pressure within the processing chamber 210.

A temperature control system 260 is configured to control a temperature of the substrate 230 during processing. In some examples, a heater controller 264 supplies power to resistive heaters 228 arranged in the top plate 224. A cooling system 268 supplies a cooling fluid to the cooling passages 223 in the baseplate 222.

A controller 270 is configured to control the process. A reflectometry sensor 280 is arranged above the substrate 230. The reflectometry sensor 280 outputs light onto the substrate and measures light reflected by the substrate at a predetermined sampling rate in a predetermined frequency range. In some examples, the predetermined wavelength range is between 100 nm and 1000 nm. An example of a reflectometry signal is shown in FIG. 6. As will be described further below, the reflectometry signals are correlated with a reference signal and EPD is performed based on the correlation coefficients that are generated.

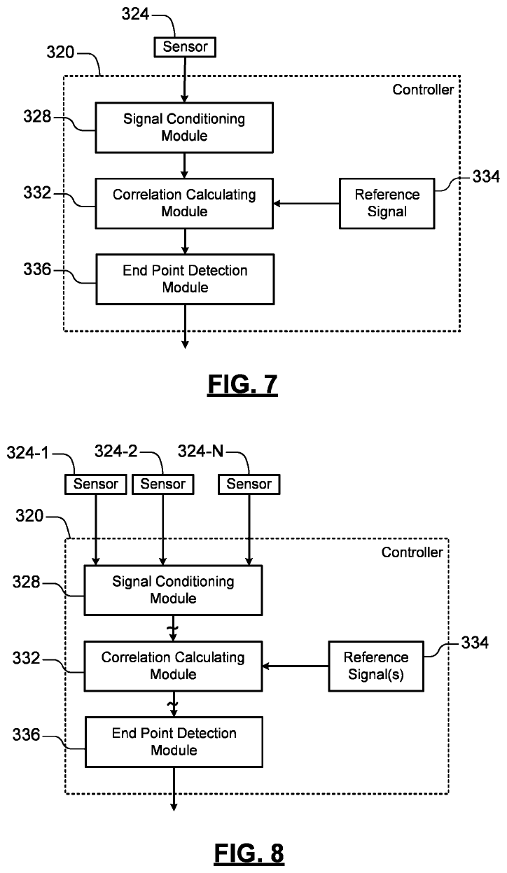

Referring now to FIGS. 7 and 8, examples of a controller 320 configured to perform EPD is shown. In FIG. 7, the controller 320 includes an optional signal conditioning module 328 to perform signal conditioning on the sensor data from a sensor 324 and/or on the correlation values that are calculated. Examples of signal conditioning includes filtering, interpolation, scaling, and/or shifting of the sensor signals and/or the reference signals. Examples of filtering may include bandpass filtering or other types of filtering. Examples of signal conditioning of the correlation values includes averaging (e.g., such as a moving average), low pass filtering, or other functions to reduce noise in the correlation coefficients. Scaling or shifting may also be performed to mitigate negative effects arising from spectral shifts, e.g., changes in wavelength calibration from the light source or detector errors.

A correlation calculating module 332 calculates correlation coefficients based on the sensor signals and a reference signal 334. The correlation coefficients for each sample are stored. An endpoint detection module 336 receives the correlation coefficients as a function of time and selectively detects the endpoint based thereon.

In some examples, the endpoint detection module 336 monitors the correlation values for a peak correlation value and then declares the endpoint in response to a minimum correlation value occurring after the peak correlation value. In other examples, the correlation values are compared to predetermined correlation values and/or value ranges and the endpoint is declared in response to the comparison. In other examples, a minimum or maximum correlation coefficient may correspond to the endpoint. In other examples, a predetermined period after a minimum or maximum correlation coefficient may correspond to the endpoint.

In FIG. 8, two or more sensors 324-1, 324-2, . . . , and 324-N can be used, where N is an integer greater than one. The sensors 324-1, 324-2, . . . , and 324-N can be arranged in different locations as shown above. In some examples, the endpoint can be declared by the controller 320 when the correlation values of any of the sensors 324-1, 324-2, . . . , and 324-N meet predetermined criteria. In other examples, the endpoint can be declared by the controller 320 when the correlation values of M of the N sensors 324-1, 324-2, . . . , and 324-N meet predetermined criteria for the corresponding one of the sensors 324-1, 324-2, . . . , and 324-N, where M is an integer that is greater than zero and less than or equal to N.

In other examples, the controller 320 performs conventional EPD by comparing intensities at one or more predetermined frequencies to predetermined thresholds (as described above) in additional to detecting the endpoint based on the correlation values.

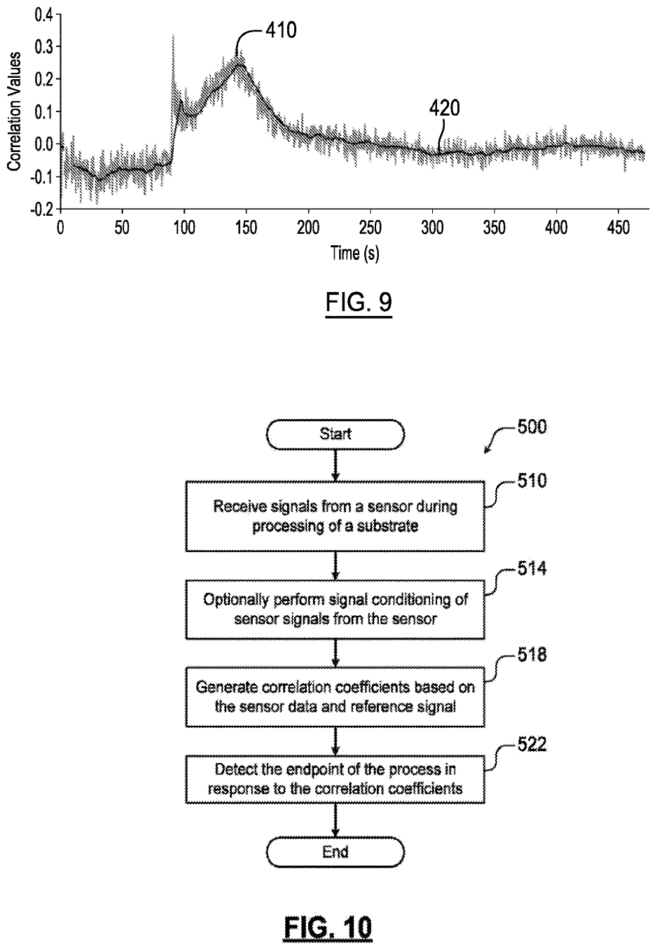

Referring now to FIG. 9, an example of correlation values as a function of time are shown. In some examples, the controller 320 performs a function on raw correlation values 410 to generate correlation values 420 that are used to detect the endpoint. For example, a moving average and/or a low pass filter are used to smooth the raw correlation values 510 and to generate the correlation values 520. The correlation values 520 are used to determine the endpoint.

Referring now to FIG. 10, a method 500 for detecting an endpoint of a substrate treatment is shown. At 510, sensor signals from one or more sensor(s) are received during processing of a substrate. At 514, signal conditioning of the sensor signals from the one or more sensor(s) is optionally performed. At 518, one or more correlation coefficients are generated based on the sensor signals and one or more reference signals. At 522, the endpoint of the process is detected in response to the one or more correlation coefficients and/or other data as described herein.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An endpoint detection system to detect an endpoint of treatment of a substrate in a processing chamber, comprising:
a first sensor configured to generate a first plurality of signals in response to one of an intensity of plasma light within a processing chamber, reflectometry from a surface of a substrate in the processing chamber, and absorption of process gases or byproducts evacuated from the processing chamber; and
a controller configured to:
calculate a first plurality of correlation coefficients in response to the first plurality of signals, respectively, and a reference signal; and
detect an endpoint of the treatment in response to the first plurality of correlation coefficients.

2. The endpoint detection system of claim 1, wherein the first plurality of signals comprise spectral signals.

3. The endpoint detection system of claim 1, wherein the first plurality of signals comprise temporal signals.

4. The endpoint detection system of claim 1, wherein the first plurality of signals comprise spectral signals and temporal signals.

5. The endpoint detection system of claim 2, wherein the first sensor comprises an optical emission spectroscopy sensor.

6. The endpoint detection system of claim 2, wherein the first sensor comprises a reflectometry sensor.

7. The endpoint detection system of claim 1, wherein the controller is configured to detect the endpoint for the substrate in response to a maximum value of the first plurality of correlation coefficients for the substrate.

8. The endpoint detection system of claim 1, wherein the controller is configured to detect the endpoint for the substrate in response to a minimum value of the first plurality of correlation coefficients following a maximum value of the first plurality of correlation coefficients for the substrate.

9. The endpoint detection system of claim 1, wherein the controller is configured to detect the endpoint for the substrate in response to a minimum value of the first plurality of correlation coefficients for the substrate.

10. The endpoint detection system of claim 1, wherein the reference signal is based on one or more signals generated at one or more endpoints for one or more reference substrates.

11. The endpoint detection system of claim 1, further comprising a second sensor configured to generate a second plurality of signals in response to another one of optical intensity of process gases within the processing chamber, reflectometry from a surface of a substrate in the processing chamber, and absorption of process gases evacuated from the processing chamber.

12. The endpoint detection system of claim 11, wherein the controller is configured to:
calculate a second plurality of correlation coefficients in response to the second plurality of signals, respectively, and a reference signal; and
detect the endpoint of the treatment in response to at least one of the first plurality of correlation coefficients and the second plurality of correlation coefficients.

13. The endpoint detection system of claim 12, wherein the controller is configured to detect the endpoint of the treatment in response to both the first plurality of correlation coefficients and the second plurality of correlation coefficients.

14. The endpoint detection system of claim 1, wherein the first sensor comprises an absorption sensor.

15. A method for detecting an endpoint of a treatment of a substrate in a processing chamber, comprising:
generating a first plurality of signals in response to one of optical intensity of process gases within the processing chamber, reflectometry from a surface of a substrate in the processing chamber, and absorption of process gases evacuated from the processing chamber;
calculating a first plurality of correlation coefficients in response to the first plurality of signals, respectively, and a reference signal; and
detecting an endpoint of the treatment in response to the first plurality of correlation coefficients.

16. The method of claim 15, wherein the first plurality of signals comprise spectral signals.

17. The method of claim 15, wherein the first plurality of signals comprise temporal signals.

18. The method of claim 15, wherein the first plurality of signals comprise spectral signals and temporal signals.

19. The method of claim 15, wherein the first plurality of signals are generated by an optical emission spectroscopy sensor.

20. The method of claim 15, wherein the first plurality of signals are generated by a reflectometry sensor.

21. The method of claim 15, further comprising detecting the endpoint for the substrate in response to a maximum value of the first plurality of correlation coefficients for the substrate.

22. The method of claim 15, further comprising detecting the endpoint for the substrate in response to a minimum value of the first plurality of correlation coefficients following a maximum value of the first plurality of correlation coefficients for the substrate.

23. The method of claim 15, further comprising detecting the endpoint for the substrate in response to a minimum value of the first plurality of correlation coefficients for the substrate.

24. The method of claim 15, wherein the reference signal is based on one or more signals generated at one or more endpoints for one or more reference substrates.

25. The method of claim 15, further comprising generating a second plurality of signals in response to another one of optical intensity of process gases within the processing chamber, reflectometry from a surface of a substrate in the processing chamber, and absorption of process gases evacuated from the processing chamber.

26. The method of claim 25, further comprising calculating a second plurality of correlation coefficients in response to both the second plurality of signals, respectively, and a reference signal; and
detecting the endpoint of the treatment in response to at least one of the first plurality of correlation coefficients and the second plurality of correlation coefficients.

27. The method of claim 25, further comprising detecting the endpoint of the treatment in response to the first plurality of correlation coefficients and the second plurality of correlation coefficients.

28. The method of claim 15, wherein the first plurality of signals are generated by an absorption sensor.
